(19) United States
(12) Patent Application Publication
(10) Pub. No.: US 2016/0104866 A1
(43) Pub. Date: Apr. 14, 2016

(54) PACKAGING STRUCTURE, MANUFACTURING METHOD THEREOF, AND DISPLAY PANEL

(71) Applicant: EverDisplay Optronics (Shanghai) Limited, Shanghai City (CN)

(72) Inventors: Maochung LIN, Shanghai City (CN); Pochun HSIEH, Shanghai City (CN); Liangjui CHANG, Shanghai City (CN); Xinran SUN, Shanghai City (CN)

(21) Appl. No.: 14/879,153

(22) Filed: Oct. 9, 2015

(30) Foreign Application Priority Data
Oct. 13, 2014 (CN) 201410539350.5

(51) Int. Cl. H01L 51/52; H01L 51/56

(52) U.S. Cl. CPC H01L 51/5253; H01L 51/56; H01L 51/5246

(57) ABSTRACT

The present disclosure discloses a packaging structure and a manufacturing method thereof, and a display panel. The packaging structure includes: a sintering part, formed between the substrate and the cover plate, wherein an encapsulation space is formed by the sintering part, the cover plate and the substrate, and the light emitting display unit is formed in the encapsulation space; and a protection part, formed on the cover plate, wherein the sintering part partially contacts with the protection part and partially contact with the cover plate. The present disclosure provides a protection part between the sintering part and the cover plate, the sintering part is divided into non-sintering regions and sintering regions by the protection part which covers a part of regions of the sintering part, thus reducing high temperature and stress generated in the process of laser sintering.

### CROSS REFERENCE TO RELATED APPLICATIONS

This application is based upon and claims priority to Chinese Patent Application No. 201410539350.5, filed on Oct. 13, 2014, the entire contents of which are incorporated herein by reference.

### TECHNICAL FIELD

The present disclosure relates to a packaging structure and a manufacturing method thereof, and a display panel, and more particularly, to a packaging structure and a manufacturing method thereof, and a display panel for organic light emitting display (OLED) technology.

### BACKGROUND

With the development of technology, the organic material is widely used in various circuit components gradually. For example, an organic light emitting display (OLED) manufactured by an organic material is in the spotlight in the display market gradually for the advantages of simple framework, good working temperature, contrast and view angle, and having light-emitting diode (LED) rectification and luminous property and so on. However, because the organic light emitting display generates a light source by using a light emitting component composed of the organic materials, it will have extremely high sensitivity to moisture. Once moisture comes into contact with the organic light emitting components, it will result in phenomena of oxidation at the cathode and peeling off of the organic compound interface, making the components generate dark spots. This will not only reduce the display quality significantly, but also result in a reduction in the display brightness, so as to reduce the lifetime of the display. Therefore, with the gradual development of the organic light emitting display, when performing the packaging of the circuit components, the sealability of the used packaging structure decides the display quality and the lifetime of the display directly.

### SUMMARY

Directing at the problems existing in the related art, the present disclosure aims to provide a packaging structure having good sealability and being able to effectively reduce the high temperature and stress generated in the process of laser sintering, a manufacturing method for the packaging structure, and a display panel including the packaging structure.

To achieve the above objects, the present disclosure provides a packaging structure for sealing a display panel. The display panel includes: a substrate, a cover plate, and a light emitting display unit provided on a surface of the substrate. The packaging structure includes:

a sintering part, formed between the substrate and the cover plate, wherein an encapsulation space is formed by the sintering part, the cover plate and the substrate, and the light emitting display unit is formed in the encapsulation space; and

a protection part, formed on the cover plate, wherein the sintering part partially contacts with the protection part and partially contact with the cover plate.

Further, a first surface area of a first surface of the protection part that contacts with the sintering part is equal to or larger than a second surface area of a surface of the sintering part that contacts with the protection part.

Further, the protection part includes shelter regions used to block a laser penetration and non-shelter regions that are penetrable by the laser, and the shelter regions and the non-shelter regions are provided alternately.

Further, the non-shelter regions are in a form of a plurality of through-holes provided on the protection part, and the part of the sintering part that is not sheltered and corresponds to bottom parts of the plurality of through-holes penetrates the plurality of through-holes and joints with the cover plate.

Further, the amount of the through-holes provided on the protection part is related to the size of the second surface area of the surface of the sintering part.

Further, the spacing between the through-holes is the same or different.

Further, a melting temperature of the protection part is greater than a melting temperature of the sintering part.

Further, a material of the sintering part includes a solidifiable material.

Further, the material of the sintering part is frit.

Further, a material of the protection part is a metal material.

Further, the light emitting display unit is an organic light emitting display unit.

Further, the cover plate is a transparent cover plate (e.g., a glass cover plate), and the substrate is a glass substrate.

Further, the sintering part and the protection part are provided between the substrate and the cover plate in an annular shape.

In another aspect, the present disclosure provides a manufacturing method for a packaging structure. The packaging structure is used for sealing a display panel. The display panel includes: a substrate, a cover plate, and a light emitting display unit provided on a surface of the substrate. The manufacturing method includes:

1) forming a protection part on an internal surface of the cover plate annularly;

2) forming a sintering part below the protection part to partially contact with the protection part and the cover plate;

3) combining the substrate and the cover plate through the sintering part, allowing the sintering part and the protection part to locate between the cover plate and the substrate; and

4) solidifying the sintering part to seal the light emitting display unit in a space surrounded by the substrate, the cover plate, the sintering part and the protection part.

Further, a first surface area of a first surface of the protection part that contacts with the sintering part is equal to or larger than a second surface area of a surface of the sintering part that contacts with the protection part.

Further, the solidifying step is performed by laser, the protection part includes shelter regions used to block a laser penetration, and the shelter regions and non-shelter regions are provided alternately.

Further, a plurality of through-holes are provided on the protection part, and part of the sintering part contacts with the cover plate through the through-holes, therefore part of the sintering part is able to be solidified by the laser penetrated through the through-holes.

Further, the amount of the through-holes provided on the protection part is related to the size of the second surface area of the surface of the sintering part.

Further, the spacing between the through-holes is the same or different.

Further, a material of the protection part includes a material which may block the laser.

Further, a material of the protection part is a metal material.

Further, the protection part is formed by evaporation plating or array manufacturing process.

Further, a material of the sintering part includes a solidifiable material, such as a frit.

Further, the material of the sintering part is glass cement.

Further, the sintering part is formed by screen printing or coating.

Further, the solidifying step is performed by laser sintering at an external surface of the cover plate corresponding to the sintering part, allowing a part of the sintering part that is not sheltered by the protection part to joint with the cover plate, so as to seal the light emitting display unit in a space surrounded by the substrate, the cover plate, the sintering part and the protection part.

In still another aspect, the present disclosure provides a display panel, including: a substrate, a cover plate, and a light emitting display unit provided on a surface of the substrate, characterized in that the display panel further includes a packaging structure which includes:

a sintering part, formed between the substrate and the cover plate; and

a protection part, formed between the cover plate and the sintering part and sheltering the sintering part partly, allowing a part of the sintering part that is not sheltered by the protection part to joint with the cover plate, so as to seal the light emitting display unit in a space surrounded by the substrate, the cover plate, the sintering part and the protection part.

Further, a first surface area of a first surface of the protection part contacting with the sintering part is equal to or larger than a second surface area of a surface of the sintering part contacting with the protection part.

Further, the protection part includes shelter regions used to block a laser to penetrate and non-shelter regions that are penetrable by the laser, and the shelter regions and the non-shelter regions are provided alternately.

Further, the non-shelter regions are a plurality of through-holes provided on the protection part, and the part of the sintering part that is not sheltered and corresponding to bottom parts of the plurality of through-holes penetrates the plurality of through-holes and joints with the cover plate.

Further, the amount of the through-holes provided on the protection part is related to the size of the second surface area of the surface of the sintering part.

Further, the spacing between the through-holes is the same or different.

Further, a melting temperature of the protection part is greater than a melting temperature of the sintering part.

Further, a material of the sintering part includes a solidifiable material.

Further, the material of the sintering part is glass cement.

Further, a material of the protection part is a metal material.

Further, the light emitting display unit is an organic light emitting display unit.

Further, the cover plate is a glass cover plate, and the substrate is a glass substrate.

Further, the sintering part and the protection part are provided between the substrate and the cover plate in an annular shape.

The present disclosure provides a protection part between the sintering part and the cover plate, the sintering part is divided into non-sintering regions and sintering regions by the protection part which covers a part of regions of the sintering part, thus controlling a laser to radiate on a sintering area of the sintering part, reducing the high temperature and stress generated in the process of laser sintering, avoiding a structure below the sintering part from being destroyed due to the high temperature, thereby guaranteeing the sealability of the packaging structure, improving the yield rate.

### BRIEF DESCRIPTION OF THE DRAWINGS

FIG. 1 is a schematic diagram of a packaging structure of a display panel in the related art;

FIG. 2A is a schematic diagram of a packaging structure of a display panel in an exemplary embodiment of the present disclosure;

FIG. 2B is an enlarged schematic diagram of part A in FIG. 2A;

FIG. 3A is a schematic diagram of a packaging structure of a display panel in another exemplary embodiment of the present disclosure;

FIG. 3B is an enlarged schematic diagram of part B in FIG. 3A;

FIG. 4 is a perspective schematic diagram of a protection part in a packaging structure of the display panel of the present disclosure; and

FIGS. 5A-5C are flow diagrams of a manufacturing method for a packaging structure of the display panel of the present disclosure.

### DESCRIPTION OF THE EMBODIMENTS

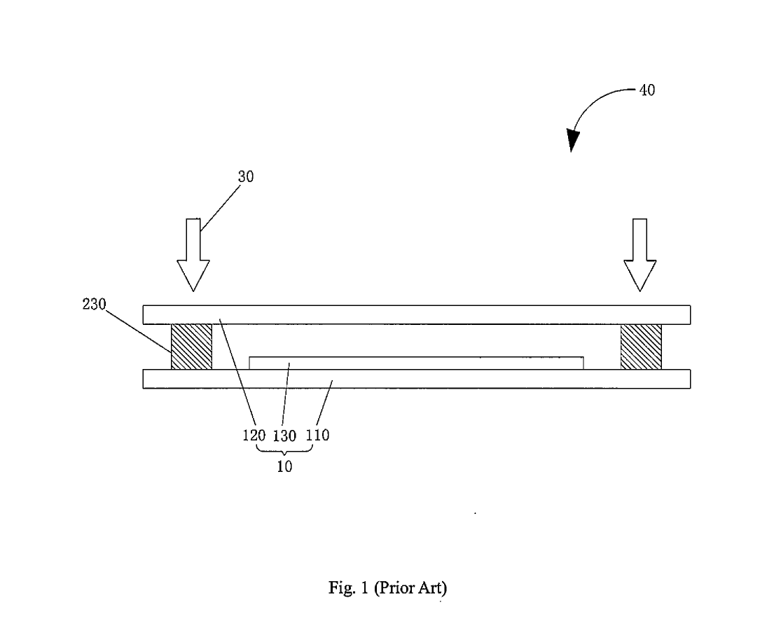

As shown in FIG. 1, it is an existing packaging structure of the organic light emitting display. The packaging structure 40 includes a sintering part 230, the sintering part 230 is formed between a substrate 110 and a cover plate 120 of a display panel 10, and the sintering part 230 directly joints with an internal surface of the substrate 110 and the cover plate 120 under the action of laser 30, so as to seal a light emitting component 130 of the display panel 10 in a space surrounded by the substrate 110, the cover plate 120 and the sintering part 230. However, at the time of performing laser sintering to the sintering part 230, it is to make laser treatment on an external surface of the cover plate 120 corresponding to the width of the sintering part 230. Because the laser irradiates the whole surface of the sintering part 230, it will generate high temperature to cause a structure below the sintering part 230 to be destroyed, badly influencing the sealability of the packaging structure and the yield rate of subsequent manufacturing processes.

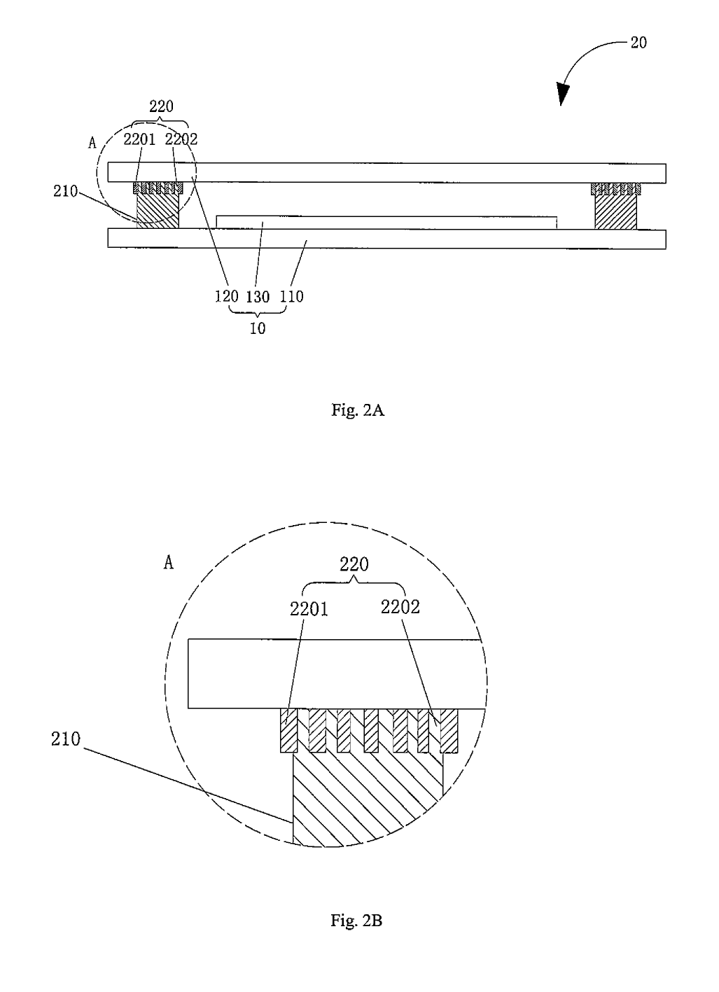

As shown in FIG. 2A and FIG. 2B, a packaging structure 20 of the present disclosure is used for sealing a display panel 10. The display panel 10 includes: a substrate 110, a cover plate 120, and a light emitting display unit 130 provided on a surface of the substrate 110. The packaging structure 20 includes: a sintering part 210, formed between the substrate 110 and the cover plate 120; and a protection part 220, formed between the cover plate 120 and the sintering part 210 and sheltering the sintering part 210 partly, allowing a part of the sintering part 210 that is not sheltered by the protection part 220 to joint with the cover plate 120, so as to seal the light emitting display unit 130 in a space surrounded by the substrate 110, the cover plate 120, the sintering part 210 and the protection part 220.

In the packaging structure 20 of the present disclosure, a protection part 220 is additionally provided between the sintering part 210 and the cover plate 120. The protection part 220 shelters a part of regions of the sintering part 210 located below the protection part 220. The protection part 220 includes shelter regions 2201 and non-shelter regions 2202, thus dividing the sintering region 210 below the protection part 220 into a plurality of sintering regions and a plurality of non-sintering regions provided alternately. The sintering region is defined as the region on the sintering part 210 that is not sheltered by the protection part 220, and the non-sintering region is defined as the region on the sintering part 210 that is sheltered by the protection part 220. With the limitation of the protection part, the laser does not irradiate the whole sintering part 210, thus reducing the high temperature and stress generated in the process of laser sintering, avoiding a structure below the sintering part 210 from being destroyed due to the high temperature, thereby guaranteeing the sealability of the packaging structure 20, improving the yield rate.

In embodiments of the present disclosure, the light emitting display unit 130 on the surface of the substrate 110 may be an organic light emitting display unit (OLED) optionally, but the present invention is not limited to this. It may be chosen as any other light emitting display unit according to the actual situation. The cover plate 120 is a transparent cover plate, e.g., a glass cover plate optionally. The substrate 110 is a glass substrate optionally. Similarly, materials of the substrate 110 and the cover plate 120 may also be any other suitable materials.

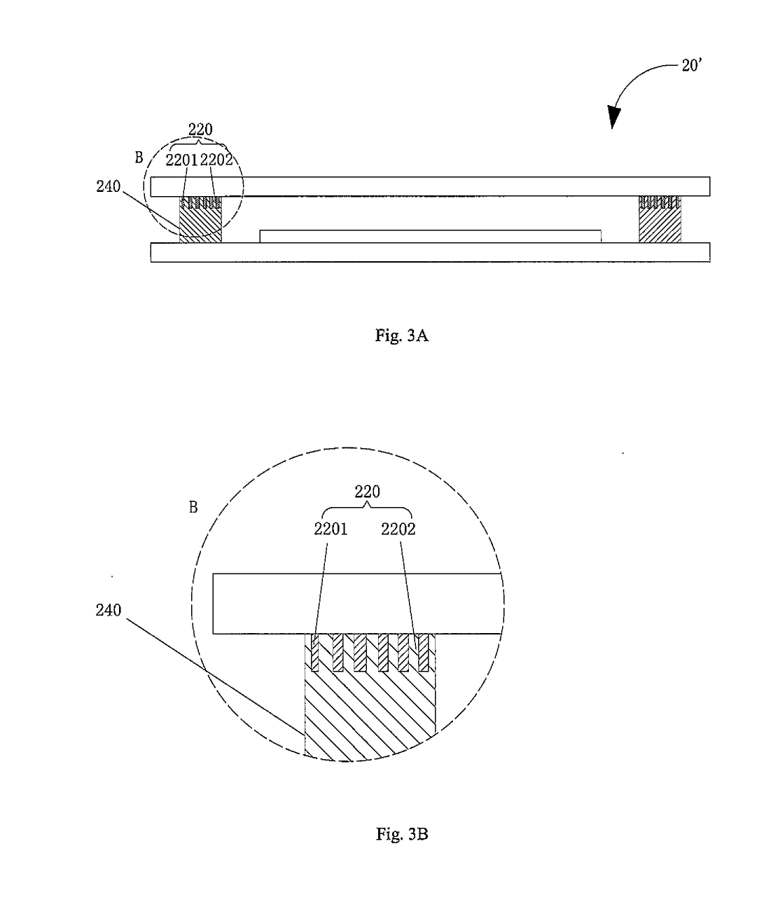

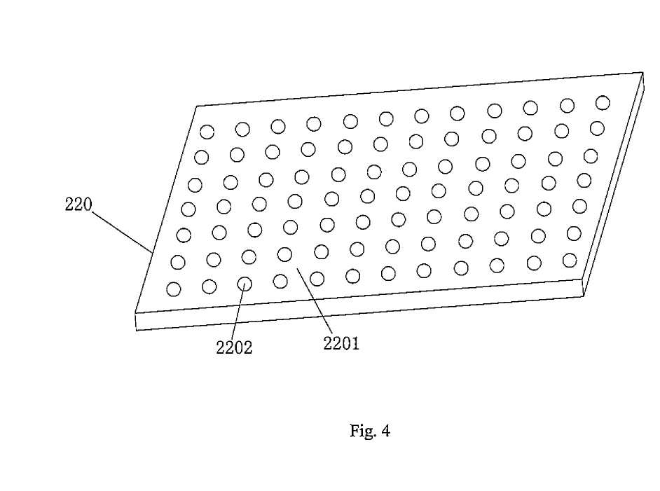

In an exemplary embodiment of the present disclosure, as shown in FIGS. 2A-2B and FIG. 4, there are a plurality of through-holes 2202 provided on the protection part 220 at intervals. The laser may pass through the through-holes 2202 and irradiate on the corresponding unsheltered regions (the sintering regions) of the sintering part 210 below the through-holes 2202. The unsheltered parts of the sintering part 210 penetrate the plurality of through-holes 2202, and joint with the cover plate 120 under the action of the laser. In order to largely reduce the influence caused by the high temperature generated by the laser, it is usually chosen that a first surface area Si of a first surface of the protection part contacting with the sintering part 210 is equal to or larger than a second surface area S2 of a surface of the sintering part contacting with the protection part 220, making most regions on the sintering part 210 sheltered, i.e., the area of the non-sintering regions is larger than the area of the sintering regions. The present invention is not limited to this. As shown in FIGS. 3A-3B, it may be also chosen that a first surface area S1 of a first surface of the protection part contacting with the sintering part 210 is smaller than a second surface area S2 of a surface of the sintering part contacting with the protection part 220.

The amount of the through-holes 2202 provided on the protection part 220 is related to the size of the second surface area S2 of the surface of the sintering part 210. Out of consideration for the jointing stability of the sintering part 210 and the cover plate 120, generally speaking, the larger the area of the second surface S2 is, the more the amount of the through-holes 2202 may be provided. In addition, the aperture size of the through-holes 2202 and the spacing between the apertures will also influence the jointing stability of the sintering part 210 and the cover plate 120. Therefore, the aperture size of the through-holes 2202 and the spacing between the through-holes 2202 may be further limited. For example, the spacing between the through-holes 2202 may be set same or different, but the present invention is not limited to this. Those skilled in the art may alter or change such settings according to the actual needs.

A material of the sintering part 210 includes a solidifiable material, for example, may be frit. A material of the protection part 220 may include a material which may block the laser, for example, may be a metal material, having such material characteristics: (1) high heat conductivity; and (2) low expansion coefficient. For example, the material of the protection part 220 may be Ti—Al—Ti, Al, Au, Cu and so on, besides the function of blocking the laser, they also conduct the heat energy generated at the time of laser sintering to the cover plate 120, so as to further reduce the contact temperature of the sintering part 210 and a structure therebelow, thus effectively avoiding the structure therebelow from being destroyed. Moreover, a melting temperature of the protection part 220 needs to be greater than a melting temperature of the sintering part 210.

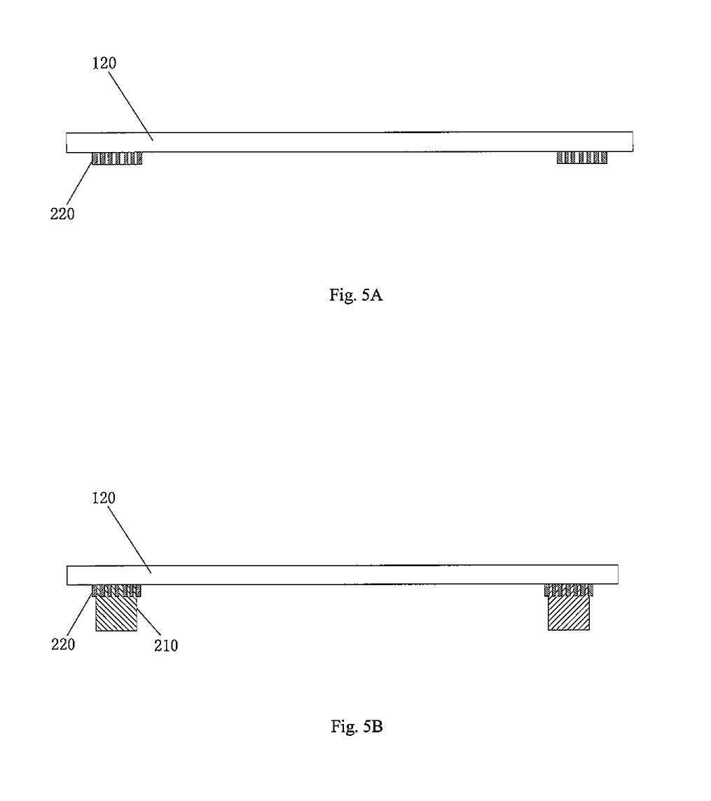

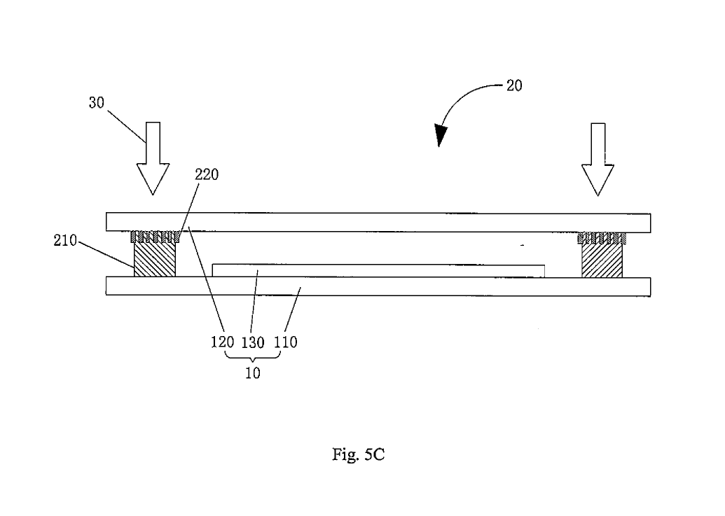

Hereinafter, the manufacturing method for the packaging structure 20 of the present disclosure will be further described. FIGS. 5A-5C are schematic diagrams of a manufacturing method for a packaging structure 20 of the present disclosure.

As shown in FIG. 5A, 1) forming a protection part 220 on an internal surface of the cover plate 120; wherein, the structure of the protection part 220 has been illustrated in the above packaging structure 20, which will not be repeated herein. The protection part 220 may be formed by evaporation plating or array manufacturing process, wherein the steps of array manufacturing process are generally as follows: (1) Forming a protection part film layer using PECVD or evaporation plating; (2) Patterning the protection part using a mask via yellow light developing and etching manufacturing process; and (3) Forming the protection part after cleaning the cover plate.

As shown is FIG. 5B, 2) forming a sintering part 210 below the protection part 220; wherein, the structure of the sintering part 210 has been illustrated in the above packaging structure 20, which will not be repeated herein, and the sintering part 210 may be formed by screen printing or coating.

As shown in FIG. 5C, 3) packaging and pressing the substrate 110 and the cover plate 120, allowing the sintering part 210 and the protection part 220 to locate between the cover plate 120 and the substrate 110, and allowing the protection part 220 to shelter the sintering part 210 partly; 4) solidifying the sintering part 210, allowing a part of the sintering part 210 that is not sheltered by the protection part to joint with the cover plate 120. In the present embodiment, the solidifying the sintering part in the step 4) is to perform sintering with laser 30 at an external surface of the cover plate 120 corresponding to the sintering part 210, allowing a part of the sintering part 210 that is not sheltered by the protection part 220 to joint with the cover plate 120, so as to seal the light emitting display unit 130 in a space surrounded by the substrate 110, the cover plate 120, the sintering part 210 and the protection part 220.

The embodiment of the present disclosure provides a display panel 10, including: a substrate 110, a cover plate 120, and a light emitting display unit 130 provided on a surface of the substrate 110. The display panel 10 is sealed by the above packaging structure 20, wherein the packaging structure 20 has been specifically illustrated in the above embodiments, which will not be repeated herein.

The exemplary embodiments of the present disclosure have been shown and described in detail as above. It should be understood that the present disclosure is not limited to the disclosed embodiments. Instead, the present disclosure is intended to encompass various modifications and equivalent arrangements within the scope of the appended claims.

What is claimed is:

1. A packaging structure for sealing a display panel, the display panel comprising a substrate, a cover plate, and a light emitting display unit provided on a surface of the substrate, the packaging structure comprising:
a sintering part, formed between the substrate and the cover plate, wherein an encapsulation space is formed by the sintering part, the cover plate and the substrate, and the light emitting display unit is formed in the encapsulation space; and
a protection part, formed on the cover plate, wherein the sintering part partially contacts with the protection part and partially contact with the cover plate.

2. The packaging structure according to claim 1, wherein, a first surface area of a first surface of the protection part that contacts with the sintering part is equal to or larger than a second surface area of a surface of the sintering part that contacts with the protection part.

3. The packaging structure according to claim 1, wherein, the protection part comprises shelter regions used to block a laser penetration and non-shelter regions that are penetrable by the laser, and the shelter regions and the non-shelter regions are provided alternately.

4. The packaging structure according to claim 3, wherein the non-shelter regions are in a form of a plurality of through-holes provided on the protection part at intervals, and the part of the sintering part that is not sheltered and corresponds to bottom parts of the plurality of through-holes penetrates the plurality of through-holes and joints with the cover plate.

5. The packaging structure according to claim 1, wherein, a melting temperature of the protection part is greater than a melting temperature of the sintering part.

6. The packaging structure according to claim 1, wherein, a material of the sintering part comprises a solidifiable material.

7. The packaging structure according to claim 6, wherein, the material of the sintering part is frit.

8. The packaging structure according to claim 1, wherein, a material of the protection part is a metal material;
the light emitting display unit is an organic light emitting display unit; and
the cover plate is a transparent cover plate, and the substrate is a glass substrate.

9. The packaging structure according to claim 1, wherein, the sintering part and the protection part are provided between the substrate and the cover plate in an annular shape.

10. A manufacturing method for a packaging structure, the packaging structure being used for sealing a display panel, the display panel comprising a substrate, a cover plate, and a light emitting display unit provided on a surface of the substrate, the manufacturing method comprising:
1) forming a protection part on an internal surface of the cover plate annularly;
2) forming a sintering part below the protection part to partially contact with the protection part and the cover plate;
3) combining the substrate and the cover plate through the sintering part, allowing the sintering part and the protection part to locate between the cover plate and the substrate; and
4) solidifying the sintering part to seal the light emitting display unit in a space surrounded by the substrate, the cover plate, the sintering part and the protection part.

11. The manufacturing method for the packaging structure according to claim 10, wherein, a first surface area of a first surface of the protection part that contacts with the sintering part is equal to or larger than a second surface area of a surface of the sintering part that contacts with the protection part.

12. The manufacturing method for the packaging structure according to claim 10, wherein, the solidifying step is performed by laser, the protection part comprises shelter regions used to block laser penetration, and the shelter regions and non-shelter regions are provided alternately.

13. The manufacturing method for the packaging structure according to claim 12, wherein, a plurality of through-holes are provided on the protection part, and part of the sintering part contacts with the cover plate through the through-holes, therefore part of the sintering part is able to be solidified by the laser penetrated through the through-holes.

14. The manufacturing method for the packaging structure according to claim 10, wherein, a material of the protection part is a metal material;
the protection part is formed by evaporation plating or array manufacturing process;
a material of the sintering part comprises frit; and
the sintering part is formed by screen printing or coating.

15. The manufacturing method for the packaging structure according to claim 10, wherein, the solidifying step is performed by laser sintering at an external surface of the cover plate corresponding to the sintering part, allowing a part of the sintering part that is not sheltered by the protection part to joint with the cover plate, so as to seal the light emitting display unit in a space surrounded by the substrate, the cover plate, the sintering part and the protection part.

16. A display panel, comprising a substrate, a cover plate, and a light emitting display unit provided on a surface of the substrate, wherein, the display panel further comprises a packaging structure, and the packaging structure comprises:
a sintering part, formed between the substrate and the cover plate; and
a protection part, formed between the cover plate and the sintering part and sheltering the sintering part partly, allowing a part of the sintering part that is not sheltered by the protection part to joint with the cover plate, so as to seal the light emitting display unit in a space surrounded by the substrate, the cover plate, the sintering part and the protection part.

17. The display panel according to claim 16, wherein, a first surface area of a first surface of the protection part contacting with the sintering part is equal to or larger than a second surface area of a surface of the sintering part contacting with the protection part.

18. The display panel according to claim 16, wherein, the protection part comprises shelter regions used to block a laser to penetrate and non-shelter regions that are penetrable by the laser, and the shelter regions and the non-shelter regions are provided alternately.

19. The display panel according to claim 18, wherein, the non-shelter regions are a plurality of through-holes provided on the protection part, and the part of the sintering part that is not sheltered and corresponding to bottom parts of the plurality of through-holes penetrates the plurality of through-holes and joints with the cover plate.

20. The display panel according to claim 16, wherein, a melting temperature of the protection part is greater than a melting temperature of the sintering part;
a material of the sintering part comprises a solidifiable material;
a material of the protection part is a metal material;
the light emitting display unit is an organic light emitting display unit;
the cover plate is a glass cover plate, and the substrate is a glass substrate; and
the sintering part and the protection part are provided between the substrate and the cover plate in an annular shape.
